(19) United States
(12) Patent Application Publication
(10) Pub. No.: US 2009/0140263 A1
(43) Pub. Date: Jun. 4, 2009

(54) METHOD FOR DIAMOND SURFACE TREATMENT AND DEVICE USING DIAMOND THIN FILM

(76) Inventors: Hitoshi Umezawa, Tsukuba-shi (JP); Shinichi Shikata, Tsukuba-shi (JP); Kazuhiro Ikeda, Itami-shi (JP)

Correspondence Address: OSTROLENK FABER GERB & SOFFEN, 1180 AVENUE OF THE AMERICAS, NEW YORK, NY, 100368403, US

(21) Appl. No.: 12/300,040

(22) PCT Filed: Apr. 27, 2007
(86) PCT No.: PCT/JP2007/059191

§ 371 Date: Nov. 7, 2008

(30) Foreign Application Priority Data
May 10, 2006 (JP) 2006-130949

(51) Int. Cl. H01L 29/16; H01L 21/22

(52) U.S. Cl. 257/77; 438/105; 257/E21.135; 257/E29.082

(57) ABSTRACT

A method for surface treatment of diamond comprising exposing the surface of diamond to UV light containing wavelengths of 172 nm to 184.9 nm and 253.7 nm at an integrated exposure of 10 to 5,000 J/cm² in an environment of an atmosphere having an oxygen concentration of 20 to 100% and an ozone concentration of 10 to 500,000 ppm to adsorb oxygen on the surface of diamond.

### TECHNICAL FIELD

A diamond semiconductor device manufactured by using a diamond surface treatment method and a diamond thin film of the present invention can be used as a power semiconductor device in the fields of various types of industrial equipment such as high-voltage pulse generators including, for example, electron beam irradiation apparatuses, ion implanters, laser generators, X-ray generators, other particle beams generators, plasma generators; high-voltage supply equipment for electric trains and automobiles; and electricity generating/receiving/transmitting equipment, as well as household electrical appliances.

The diamond power semiconductor device of the present invention enables miniaturization of equipment that handles high voltage, and a reduction in consumption of electricity. Not only will this device replace existing power devices including power devices manufactured from silicon, SiC and GaN but it is also expected to be used in the development of new applications in using high voltage industrial fields.

### BACKGROUND ART OF THE INVENTION

Regarding power semiconductor elements, various types of diodes and transistors have been developed by using new wide-band-gap raw materials such as SiC and GaN, and applications in the fields of various types of industrial equipment such as high-voltage pulse generators including, for example, electron beam irradiation apparatuses, ion implanters, laser generators, X-ray generators, other particle beams generators, plasma generators; high-voltage supply equipment for electric trains and automobiles; and electricity generating/receiving/transmitting equipment; as well as household electrical appliances, have been studied. Realization of devices taking advantage of characteristics of wide-band gap and electrical equipment using devices which cannot be realized using conventional silicon power semiconductor devices is expected. In order to realize the above-described applications, it is absolutely necessary to obtain devices that can withstand a large pressure at high voltages. Therefore, research and development is being advanced in terms of raw materials and structures.

In terms of raw materials which have a high dielectric breakdown voltage have shown promise. Search and development have been carried out on raw materials, including silicon carbide (SiC) such as 4HSiC and 6HSiC; nitrides such as gallium nitride (GaN) and aluminum gallium nitride (AIGaN); combination there of; and carbon-based raw materials such as diamond, nanocrystal diamond and carbon nanotube (CNT). Of these raw materials, diamond has a wide band gap of 5.5eV, as well as excellent thermal conductivity, dielectric breakdown voltage, and thermal resistance. Thus, it is suggested that diamond is a raw material superior to silicon carbide and gallium nitride (refer to Non-patent Document 1). Diamond has a value for all of the characteristics above more than three times greater than the value for other raw materials (silicon carbide and gallium nitride).

Since a Schottky barrier diode which is the basis of the device has been studied as an application of a diamond power semiconductor, the Schottky barrier diode will be described herein as an example.

In order to allow a diamond power semiconductor devise to act at a high power for a prolonged period of time under extreme environments, it is necessary to reduce leakage current upon application of diode reverse voltage. Where a high-withstanding pressure/high-electric current element is actually realized in the field of power semiconductor devices, a vertical structure is often adopted at which a Schottky electrode and an ohmic electrode are disposed respectively at the upper part and the lower part so that electric current is allowed to flow vertically. Although vertical devices using diamond have been developed, sufficient thermal conductivity, dielectric breakdown voltage, and thermal resistance have not yet been obtained. Thus, the reverse leakage current, which is important in a power device, is large, that is, the reverse leakage current value may be 1×10⁻⁵A/Cm². Further, the cause of the significant reverse leakage current and countermeasures to reduce the reverse leakage current had not yet been found (Non-patent Document 2).

Reverse electric-current characteristics of diodes include, in general, thermal field emission, thermal field emission due to a decrease in field induction barriers, thermal excitation field emission, and electric field emission (Non-patent Document 3). The method for increasing rectifying properties of a diode (reduce reverse current leakage) includes using high insulation diamond in a metal contact layer (Patent Document 1, Patent Document 2 and Patent Document 3), and avoiding defective regions (Patent Document 4).

In the above-described methods, to attain Schottky contact (especially on the oxygen terminated surface), the oxygen terminated surface is exposed to oxygen/fluorine plasma (Patent Document 5 and Patent Document 6) and then the surface is oxidation by acids (Patent Document 7). It is, however, difficult to control the Schottky barrier height and to obtain a barrier with a height of more than 2eV and with excellent reproducibility (Non-patent Documents 4-28).

Non-patent Document 1: lEEE Electron Device Letters, 25, 298 (2004)
Non-patent Document 2: W. Huang et al, 17^{th} Int'l Symp. Power Semicond. Devices and IC's, Proc. p319 (2005)

### Non-patent Document 3: S. M. Sze, “Physics of Semiconductor Devices” Wiley—Interscience, 1981.

Non-patent Document 4: Mead et al., Phys. Rev. 134 (1964) A713.

### Non-patent Document 5: Glover et al., Solid State Electron. 16 (1973) 973.

Non-patent Document 6: Mead et al., Phys. Lett. 58A (1976) 249.

### Non-patent Document 7: Himpsel et al., Solid State Commun. 36 (1980) 631.

Non-patent Document 8: Himpsel et al., J. Vac. Sci. Tech. 17 (1980) 1085.

### Non-patent Document 9: Geis et al., IEEE EDL, 8 (1987) 341.

Non-patent Document 10: Hicks et al., J. Appl. Phys. 65 (1989) 2139.
Non-patent Document 11: Shiomi et al., Jpn. J. Appl. Phys. 28 (1989) 758.
Non-patent Document 12: Hicks et al., J. Appl. Phys. 65 (1989) 2139.
Non-patent Document 13: Grot et al., J. Mater. Res. 5 (1990) 2497.
Non-patent Document 14: Weide et al., J. Vac. Sci. Tech. B 10 (1992) 1940.
Non-patent Document 15: Tachibana et al., Phys. Rev. B 45 (1992) 11975.

### Non-patent Document 16: Ebert et al., IEEE EDL, 15 (1994) 289.

Non-patent Document 17: Kiyota et al. Appl. Phys. Lett. 67 (1995) 3596.
Non-patent Document 18: Vescan et al., Diam. Relat. Mater. 4 (1995) 661.
Non-patent Document 19: Ebert et al., Diam. Relat. Mater. 6 (1997) 329.
Non-patent Document 20: Vescan et al., Diam. Relat. Mater. 7 (1998) 581.
Non-patent Document 21: Yamanaka et al., J. Appl. Phys. 84 (1998) 6095.
Non-patent Document 22: Yamanaka et al., Diam. Relat. Mater. 9 (2000) 956.
Non-patent Document 23: Chen et al., Appl. Phys. Lett. 16 (2003) 4367.
Non-patent Document 24: Chen et al., Diam. Relat. Mater. 12 (2003) 1340.
Non-patent Document 25: Aleksov et al., Semicond. Sci. Tech. 18 (2003) S59.
Non-patent Document 26: Butler et al., Semicond. Sci. Tech. 18 (2003) S67.
Non-patent Document 27: Integrated exposure Craciun et al., Diam. Relat. Mater. 13 (2004) 292.
Non-patent Document 28: Chen et al., J. Vac. Sci. Tech. B 22 (2004) 2084.
Patent Document 1: Japanese Published Unexamined Patent Application No. Hei-03-120865
Patent Document 2: Japanese Published Unexamined Patent Application No. Hei-03-278474
Patent Document 3: Japanese Published Unexamined Patent Application No. Hei-04-302172
Patent Document 4: Japanese Published Unexamined Patent Application No. Hei-04-188766
Patent Document 5: Japanese Published Unexamined Patent Application No. Hei-4-26161
Patent Document 6: Japanese Published Unexamined Patent Application No. Hei-5-24990
Patent Document 7: Japanese Published Unexamined Patent Application No. Hei-5-24990

### DETAILED DESCRIPTION OF THE INVENTION

### Problems to be Solved by the Invention

It is expected from the theoretical properties that diamond can be used in power semiconductor devices. However it is known that diamond power semiconductor devices has a low ability to withstand pressure and has a large reverse leakage current. In addition, measures to improve these properties are still unknown. Wide-band-gap raw materials, such as SiC, which have been studied so far are unable to realize the above properties at all. In addition, there was the problem in that uniformity of an element made from these materials is unstable. The Schottky barrier height is particularly unstable depending on the surface length of oxidation treatment and the treatment temperatures.

The present inventors have considered the diamond surface treatment methods and the Schottky barrier height formed on a metal-diamond boundary surface, from a perspective different from the conventional findings, thereby providing a method for obtaining a diamond structure with an improved ability withstand pressure and a smaller reverse leakage current, and a device using the diamond thin film made from said diamond.

### Means for Solving the Problem

The present inventors have diligently studied the above problem and found that UV exposure can be conducted in an oxygen atmosphere at room temperature or where a substrate is heated, or a substrate can be exposed to an ozone atmosphere to stabilize the Schottky barrier height at 2eV or higher, thus creating a diamond power semiconductor device using diamond structured so as to reduce a reverse leakage current.

In other words, the present invention is a method for diamond surface treatment in which the surface of a diamond is exposed to UV rays containing wavelengths of 172 nm or 184.9 nm, and 253.7 nm at an integrated exposure of 10 to 5,000 J/cm² in an atmosphere having an oxygen concentration of 20% to 100% or ozone concentrations of 10 ppm to 500,000 ppm, thereby adsorbing oxygen on the surface of diamond.

Further, in the present invention, prior to the above-described UV treatment, diamond can be subjected to a hot mixed-acid treatment.

Further, in the present invention, crystalline-structured diamond selected from crystalline structured faces (001), (111) and (110), and faces equivalent to these faces can be adopted.

Further, in the present invention, as a semiconductor diamond, a diamond thin film to which an impurity capable of forming a p-type or an n-type semiconductor layer is added can be adopted.

Further, in the present invention, phosphorous can be given as an impurity which forms an n-type semiconductor layer.

Still further, in the present invention, boron can be given as an impurity which forms a p-type semiconductor layer.

In addition, in the present invention, when an epitaxial diamond thin film is made by a microwave CVD method, it is possible to add an impurity capable of forming an n-type or a p-type semiconductor layer.

Further, the present invention is a diamond Schottky barrier diode having a vertical structure in which a Schottky electrode and an ohmic electrode are disposed respectively on the upper face and the lower face on either side of a semiconductor diamond layer, wherein the diamond semiconductor layer is a diamond semiconductor layer obtained by any one of the above-described methods for diamond surface treatment.

Further, the present invention is a diamond pin diode having a vertical structure in which a p-type electrode and an n-type electrode are disposed separately on the upper face and on the lower face respectively, among power semiconductor devices having a substrate, a semiconductor, the p-type electrode and the n-type electrode, wherein the diamond semiconductor layer is obtained by any one of the above-described methods for diamond surface treatment.

Still further, the present invention is an MOS transistor having a vertical structure made up of a substrate, a p-type semiconductor, an n-type semiconductor, a gate electrode and a gate insulation film and utilizing the p-type semiconductor or the n-type semiconductor as a drift layer, wherein the p-type semiconductor or the n-type semiconductor is a diamond semiconductor layer obtained by any one of the above-described methods of diamond surface treatment.

In addition, the present invention is realized as a diamond thyristor having a vertical structure in which the p-type semiconductor and the n-type semiconductor are stacked in four layers in a power semiconductor device.

It is noted that the present invention is applicable not only to the vertical structure used in power devices in general but also applicable to a horizontal structure used in various types of the above devices.

### Advantageous Effects of the Invention

The diamond power semiconductor element of the present invention is able to suppress the reverse leakage current of devices such as various types of diodes, transistors and thyristors to a lower level, able to stabilize diode characteristics (on-voltage, in particular) which would be otherwise not uniform, and also able to withstand a high reverse voltage when used in various types of power semiconductor circuits. More specific applications of the present invention include diamond power semiconductor elements used in the fields of various types of industrial equipment including high-voltage pulse generators including, for example, electron beam irradiation apparatuses, ion implanters, laser generators, X-ray generators, other particle beams generators, plasma generators;, high-voltage supply equipment for electric trains and automobiles; electricity generating/receiving/transmitting equipment; and household electrical appliances.

### BRIEF DESCRIPTION OF THE DRAWINGS

FIG. 1a shows changes in diode characteristics due to a difference in oxidation treatments (hot mixed-acid treatment and UV exposure ozone treatment).

FIG. 1b shows changes (logarithmic display) in diode characteristics due to a difference in oxidation treatments (hot mixed-acid treatment and UV exposure ozone treatment).

FIG. 2 shows a difference in Schottky barrier due to a difference in oxidation treatments.

FIG. 3 shows scattering in the barrier height of Schottky barrier diodes (including an example disclosed in the Non-patent Documents).

FIG. 4 shows treatment methods and oxygen peak intensities measured by XPS.

FIG. 5 shows characteristics of elements subjected to UV zone treatment and hot mixed-acid cleaning after the UV ozone treatment.

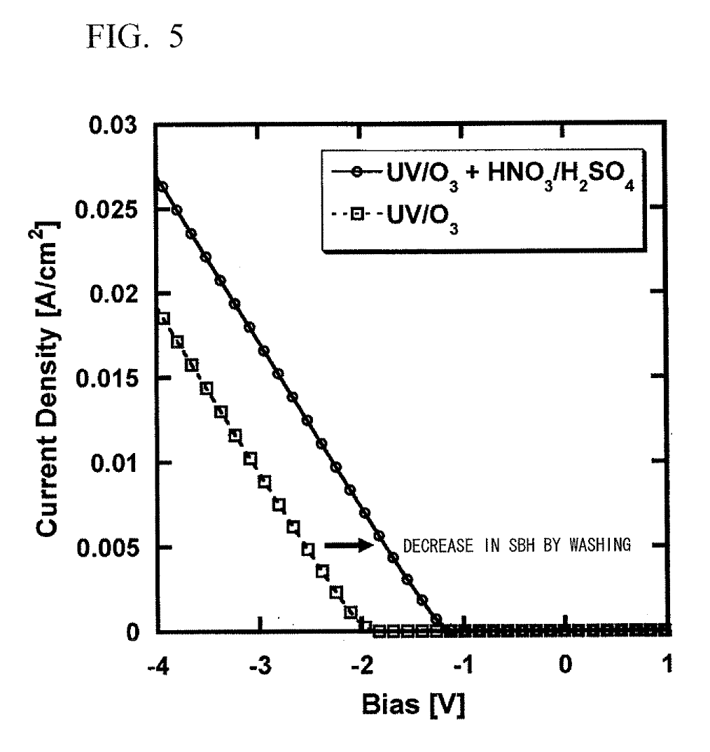

FIG. 6a shows Mo Schottky characteristics (low voltage characteristics) of elements subjected to UV ozone treatment and ozone treatment.

FIG. 6b shows Mo Schottky characteristics (reverse field characteristics) of elements subjected to UV ozone treatment and ozone treatment.

FIG. 7a shows Ru Schottky characteristics (low voltage characteristics) of elements after UV ozone treatment.

FIG. 7b shows Ru Schottky characteristics (reverse field characteristics) of elements after UV ozone treatment.

FIG. 8 shows reverse field characteristics of Al, Ti, Mo, Pt Schottky elements after UV ozone treatment.

FIG. 9 shows a Schottky barrier height and working (limit) voltage (1 μA/cm² is given as a threshold value).

### BEST MODE FOR CARRYING OUT THE INVENTION

The oxygen or ozone atmospheric environment in the present invention is an atmospheric environment having an oxygen concentration of 20% to 100% and an ozone concentration of 10 ppm to 500,000 ppm. The UV treatment of the present invention is to expose the surface of a diamond to UV rays containing wavelengths of 172 nm or 184.9 nm, and 253.7 nm. The exposure time is usually from 3 to 18 hours, although it may vary depending on the wavelength and intensity, and the integrated exposure is usually from 10 to 5,000 J/cm².

In the present invention, adsorption of oxygen on the surface of a diamond refers to oxygen which remains chemically or physically on the surface of a diamond.

The wavelengths of ultraviolet rays (UV) used in the present invention include wavelengths of 172 nm or 184.9 nm, and 253.7 nm. UV rays having a wavelength of 172 nm or 184.9 nm generate ozone, and UV rays having a wavelength of 253.7 nm destroy ozone.

The hot mixed-acid of the present invention is a mixed-acid, the temperature of which is 50° C. or higher, and the mixed-acid is a mixture of inorganic acids such as hydrochloric acid, nitric acid, and sulfuric acid. A mixture of nitric acid and hydrochloric acid is preferably used.

The diamond used in the present invention, in particular, the diamond thin film, may include crystalline structures (001), (111), and (110) and faces equivalent to the faces included in the crystalline structures can be adopted.

The basic structure of a diamond Schottky barrier diode of the present invention is made of p-type and p+-type semiconductor layers, an n-type and n+-type semiconductor layers, an ohmic electrode, a Schottky electrode, and a protective film.

Further, the basic structure of a pin diode of the present invention is made of a low impurity-concentration diamond layer, a p-type and p+-type semiconductor layers, an n-type and n+-type semiconductor layers, an ohmic electrode and a protective film.

Still further, the basic structure of an MOS transistor of the present invention is made of a p-type and p+-type semiconductor layers, an n-type and n+-type semiconductor layers, an ohmic electrode, a gate metal, a gate insulation film and a protective film.

A fabricating method to realize a diamond power semiconductor device of the present invention is to conduct this treatment on the surface of a diamond prior to the formation of a Schottky electrode. Types of power semiconductor devices of the present invention include a diamond Schottky barrier diode having a vertical structure in which a Schottky electrode and an ohmic electrode are disposed respectively on the upper face and the lower face. Further, types of diodes of the present invention include a pin diode having a vertical structure in which the p-electrode and the n-electrode are separately disposed respectively on the upper face and the lower face. Also included Are a p-type or an n-type MOS transistor having a vertical structure and a thyristor in which p-type and n-type semiconductors are stacked in four layers.

### EMBODIMENT 1

### Fabrication of Schottky Barrier Diode

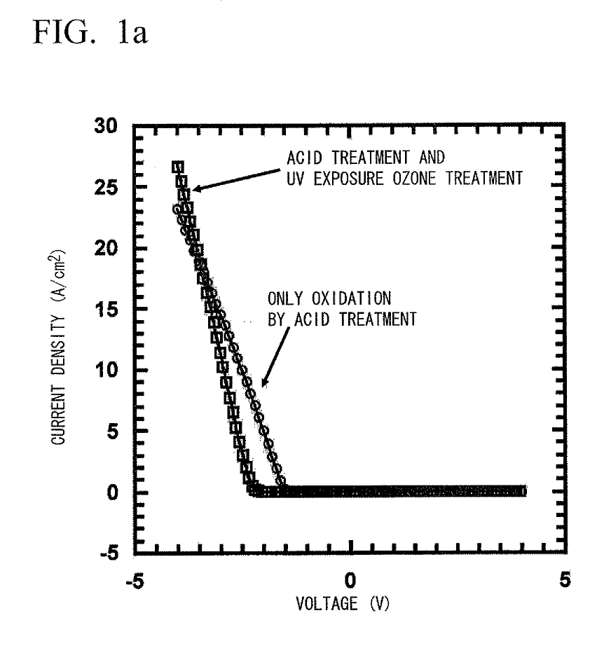

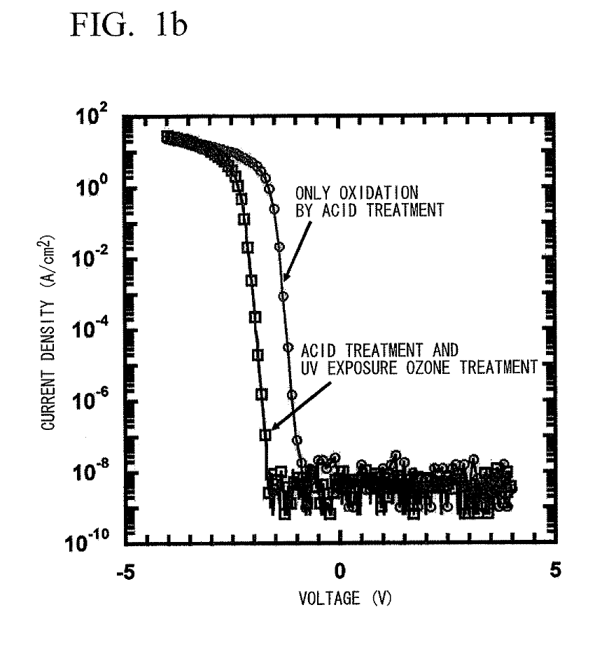

A low-concentration boron-added homoepitaxial diamond thin film which was formed in a thickness of 1 μm on a high-concentration boron-added diamond single crystal at boron concentrations of 100 ppm to 10 ppm and 1 ppm or lower with respect to carbon inside a reaction tank for microwave CVD method was used as a specimen. The acceptor concentration was 1.5×10¹⁵ to 9×10¹⁶/cm³. After cleaning of a substrate with hot mixed-acid of nitric acid and hydrochloric acid, a Ti/Pt/Au ohmic electrode was formed on the high-concentration boron-added diamond on the back of the substrate to conduct alloying annealing. Then, in an environment of an oxygen atmosphere of 50% oxygen and 50% nitrogen, the substrate was exposed to UV rays containing wavelengths of 172 nm or 184.9 nm, and 253.7 nm, and UV ray ozone concurrent treatment was conducted on the substrate at 500 ppm to 1000 ppm of ozone formed by UV rays in a ultraviolet ray intensity of 3.7 mW/cm² for approximately 18 hours (integrated exposure of 240 J/cm²). Then, a Schottky electrode of 30 to 200 μm was formed with Pt on the low concentration boron-added diamond thin film on the upper face of the substrate. The thus fabricated device was measured to reveal that a forward build-up voltage was 2.3V, and a reverse electric current was 1×10⁻⁸ A/cm² or less, with the leakage current being negligible (refer to FIG. 1b). Further, devices were experimentally fabricated in a similar manner from a plurality of substrates to evaluate the scattering of the barrier height or a Schottky barrier height characteristics. The barrier height or a Schottky barrier height, as determined from a reverse saturated current, was 2.45±0.15 eV on all the substrates.

### COMPARATIVE EXAMPLE 1

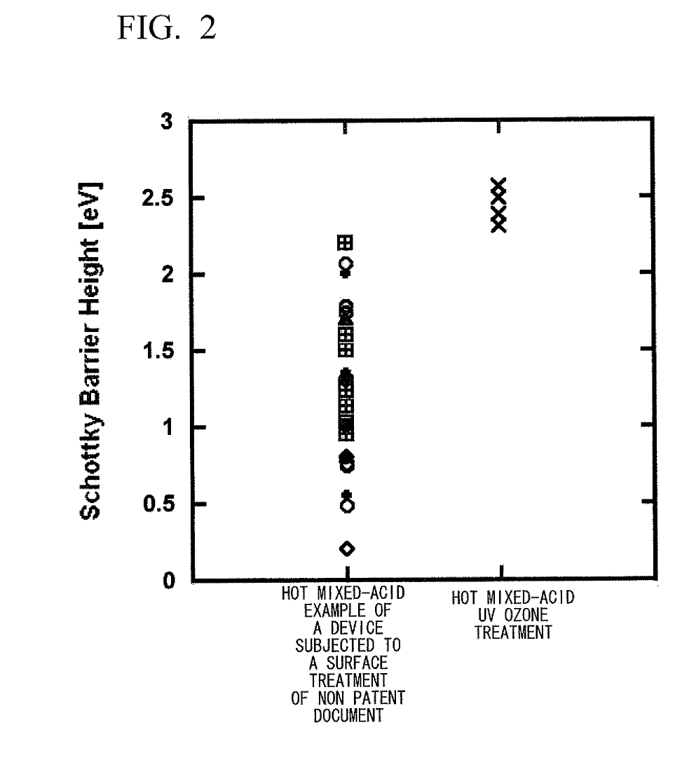

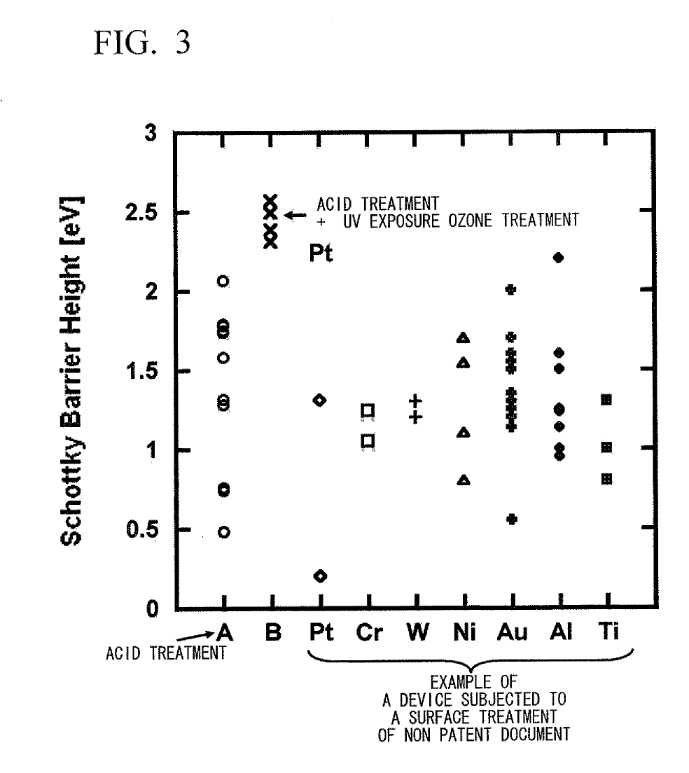

For comparative discussion, a Schottky barrier diode of the above embodiment was taken as an example. As a specimen, a low-concentration boron-added homoepitaxial diamond thin film which was formed at a thickness of 1 μm on a high-concentration boron-added diamond single crystal at boron concentrations of 100 ppm to 10 ppm and 1 ppm or lower with respect to carbon inside a reaction tank for a microwave CVD method was used. The acceptor concentration was from 1.5×10¹⁵ to 9×10¹⁶/cm³. After cleaning of a substrate with the hot mixed-acid, a Ti/Pt/Au ohmic electrode was formed on the high-concentration boron-added diamond on the back of the substrate to conduct alloying annealing. Then, a Schottky electrode of 30 to 200 pm was formed with Pt on the low concentration boron-added diamond thin film on the upper face of the substrate. The thus fabricated device was measured to reveal that a forward build-up voltage (and Schottky barrier height) varies from 0.7 to 2.2 V depending on the substrates (refer to FIG. 1a and FIG. 2). The barrier height varied similarly (0.2 to 2.5) to those described in, for example, Non-patent Documents 4 to 28 (refer to FIG. 3).

### EMBODIMENT 2

(1) Quantification of Surface Oxygen Amount

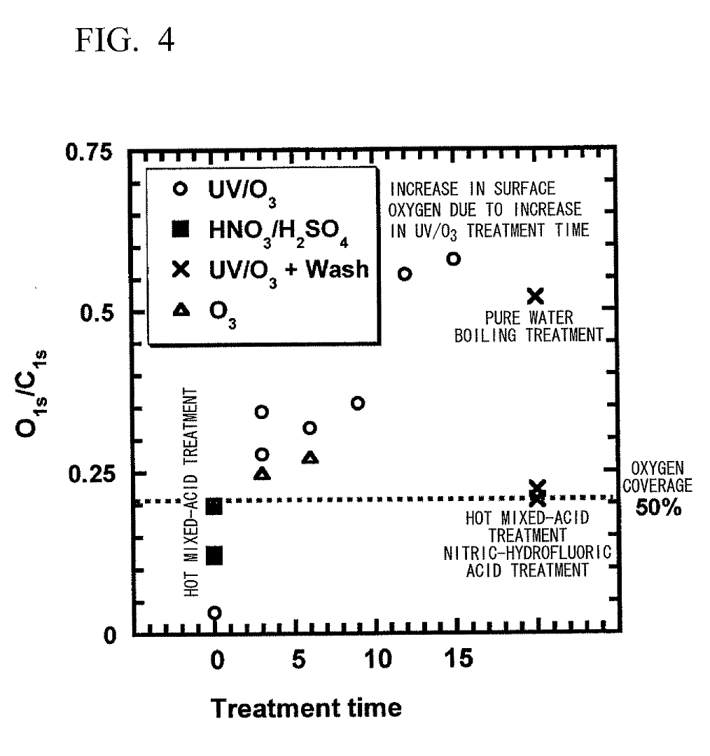

A substrate subjected to UV ozone treatment was subjected to XPS (X-ray photoelectron spectroscopy) and the amount of oxygen atoms adsorbed on the surface was measured. The measurement found peaks of carbon, oxygen, and silicon. Evaluation was made for coverage by referring to the respective peak area ratios, measurement sensitivity coefficients and mean free path of C1s photoelectrons. FIG. 4 shows a ratio of O1s peak area to C1s peak area by various treatments.

It is noted that in this measuring apparatus, the ratio of O1s/C1s, or approximately 0.2 was equivalent to approximately 50% of an amount of oxygen adsorbed by the surface of the substrate. The measurement result revealed that in the oxidation treatment by the hot mixed-acid treatment, the ratio of O1s/C1s was from approximately 0.1 to 0.2, but the concentration of oxygen adsorbed on the surface was increased in accordance with an increase in UV ozone treatment time, thus making it possible to cover the oxygen in excess of 50% of the surface coverage. This substrate was subjected to (a) pure-water boiling treatment, (b) H₂SO₄+HNO₃ (hot mixed-acid) treatment, and (c) nitric-hydrofluoric acid treatment. As a result, no great change in oxygen peak intensity in (a) pure-water boiling treatment was observed. On the contrary, in acid treatments of (b) and (c), a large decrease in the oxygen peak was observed, that is, at the same oxygen peak as found in the hot mixed-acid treatment, which was conducted as an ordinary surface oxidation treatment. Further, where only the ozone treatment (ozone concentration inside the chamber, 2 g/m³) in which an ozone generator was used was conducted, a higher oxygen coverage than a case where only the hot mixed-acid treatment was conducted was obtained. However, the oxygen coverage was lower by approximately 10% to 20% than a case where the UV ozone treatment was conducted.

FIG. 4 shows the SBD (Schottky barrier diode) characteristics of a substrate in which acid cleaning was conducted after the UV ozone treatment to decrease the oxygen coverage. Where no hot mixed-acid treatment was conducted after the UV ozone treatment, SBH was at 2.2eV with respect to Pt. However, where the hot mixed-acid treatment was conducted, the SBH was decreased to 1.57eV, which was equal to that found in an ordinary oxygen terminated diamond SBD.

### EMBODIMENT 3

### Example of Mo

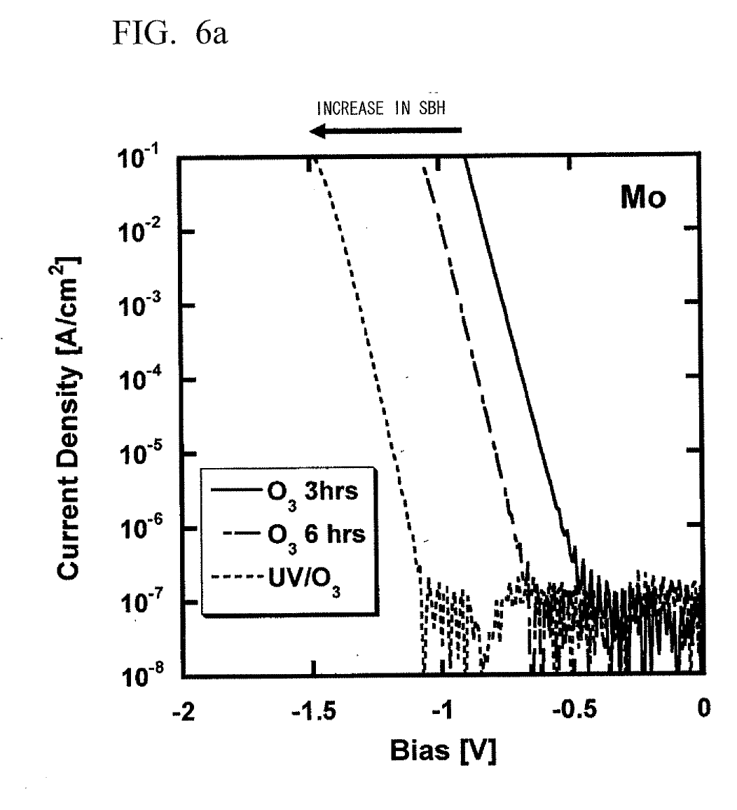

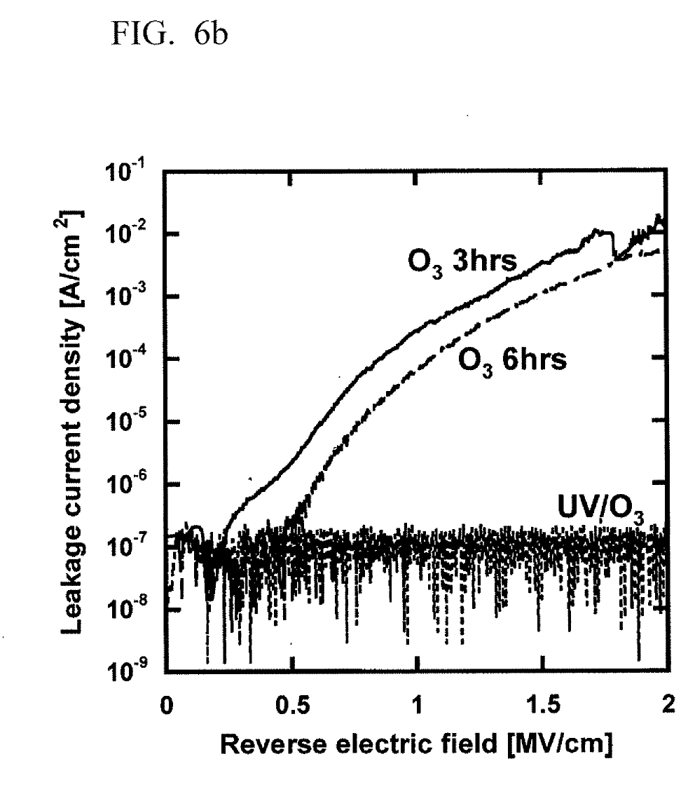

FIG. 6a is a graph showing electric characteristics of devices which have Schottky electrodes including Mo and were subjected to a UV ozone treatment or an ozone treatment according to the present invention. The Schottky barrier height (SBH) was increased in accordance with an increase in the ozone treatment time. The SBH of the elements that had been subjected to ozone free treatment with the use of Mo was 1 to 1.2eV. Where the elements were subjected to the ozone treatment for 3 and 6 hours, the respective SBHs were 1.2eV and 1.4eV. However, when the elements were subjected to the UV ozone treatment, a higher SBH of 2.5eV was observed.

FIG. 6b shows the reverse characteristics of the elements which were subjected to the ozone treatment for 3 and 6 hours and to the UV ozone treatment. Elements higher in SBH were effectively decreased in leakage current even at a high voltage. Therefore, the elements that were subjected to the UV ozone treatment had a lower leakage current than a case where they were subjected to the ozone treatment.

### EMBODIMENT 4

### Example of Ru

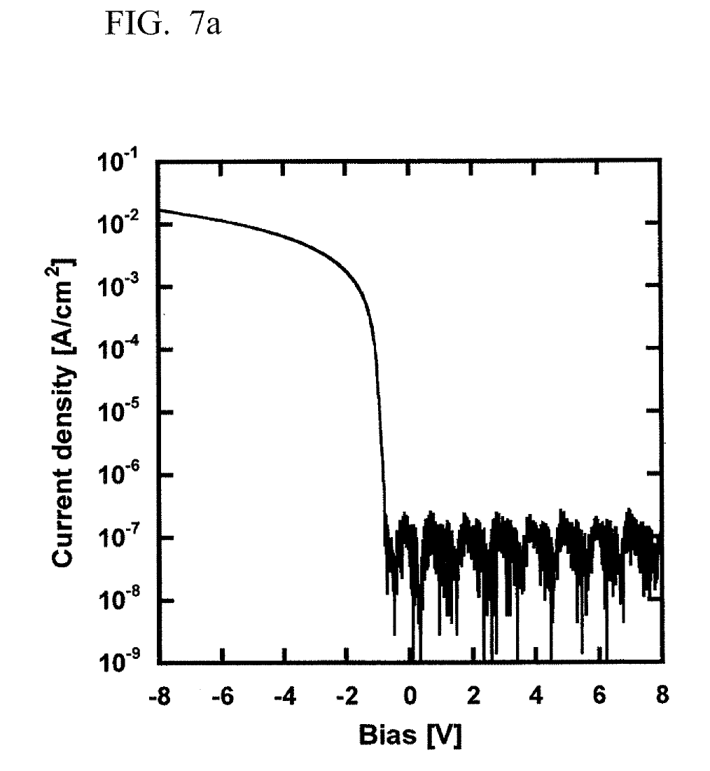

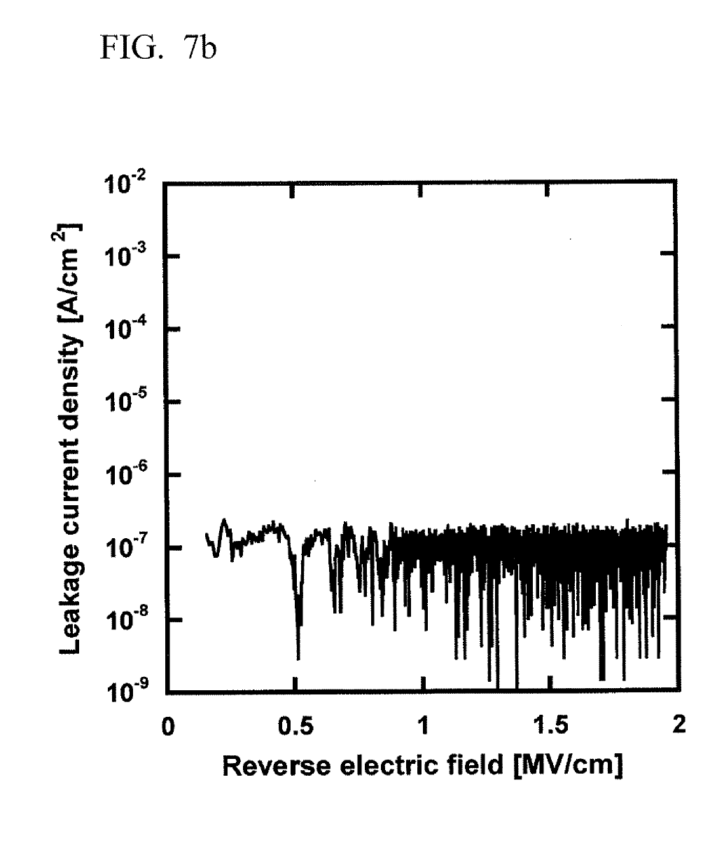

FIG. 7a and FIG. 7b show electrical characteristics found after elements at which Ru is used in a Schottky electrode were subjected to the UV ozone treatment. FIG. 7a shows forward characteristics, while FIG. 7b shows reverse leakage characteristics. No leakage current in an electric field of 2 MV/cm by the UV ozone treatment was observed.

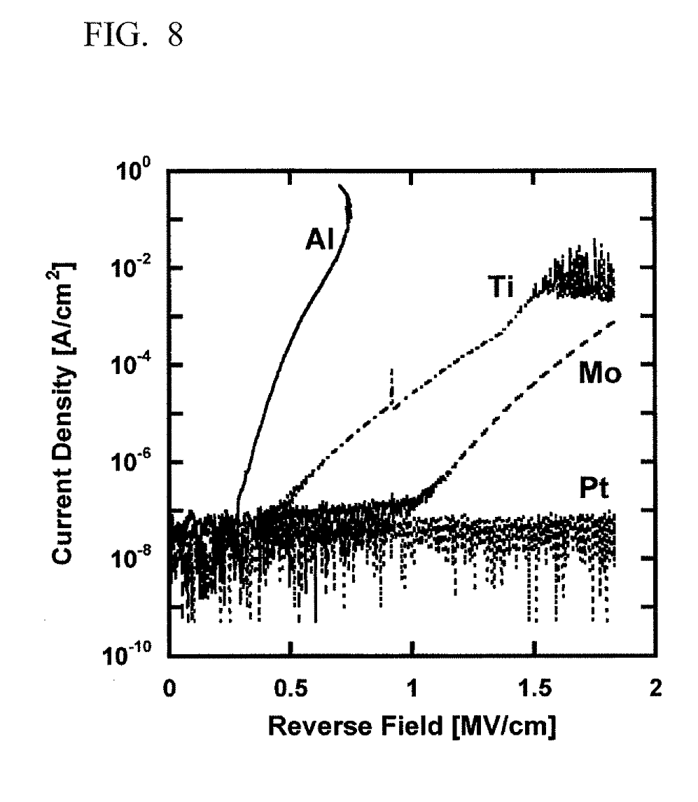

FIG. 8 shows a difference in current density depending on the type of Schottky metals.

FIG. 8 shows leakage current characteristics in a reverse electric field of an SBD in which Al, Ti, Mo and Pt were used on a substrate subjected to the UV ozone treatment for 12 hours. No leakage current up to 1.8 MV/cm in the case of Pt was observed, while a transient build-up of reverse leakage current in the case of Mo, Ti and Al was observed.

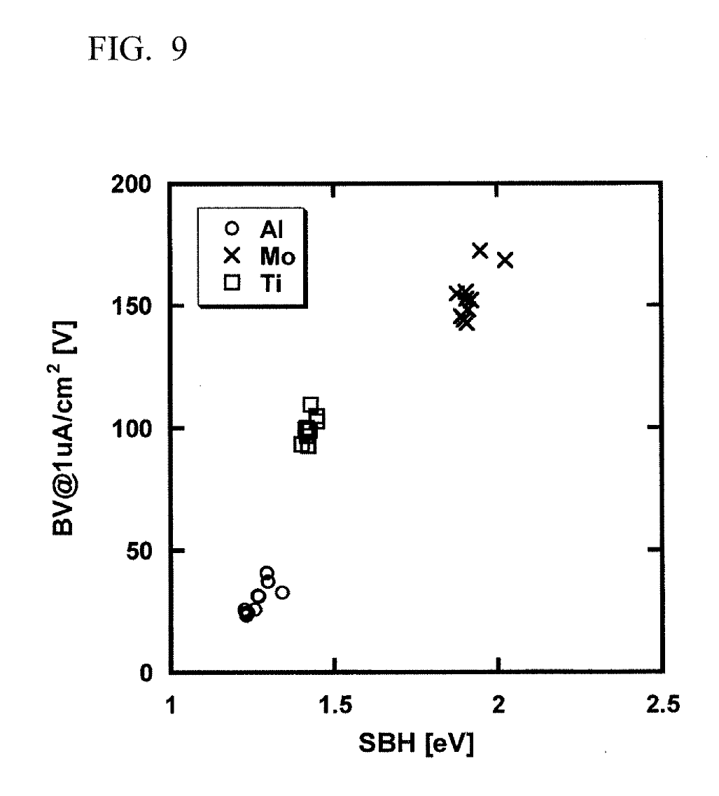

FIG. 9 shows the relationship between the working voltage and SBH where 1 μA/cm² was used as a threshold working (limit) voltage.

As shown in FIG. 9, where the SBH is high, the working voltage is high. Mo, Ru and Pt are Schottky electrode raw materials which are able to provide an SBH higher than 2eV at which a low current leakage is obtained even at a high voltage. These Schottky metals are able to suppress the reverse leakage current to a lower level.

### INDUSTRIAL APPLICABILITY

The diamond power semiconductor element of the present invention is able to suppress the reverse leakage current of various types of devices such as diodes, transistors and thyristors to a lower level, and also able to withstand a high reverse voltage when used in various types of power semiconductor circuits. More specifically, this diamond power semiconductor element can be used in the fields of various types of industrial equipment such as high-voltage pulse generators including, for example, electron beam irradiation apparatuses, ion implanters, laser generators, X-ray generators, other particle beams generators, plasma generators; high-voltage supply equipment for electric trains and automobiles; electricity generating/receiving/transmitting equipment; and household electrical appliances.

1. A diamond surface treatment method, wherein the surface of a diamond is exposed to UV rays of wavelengths of 172 nm or 184.9 nm, and 253.7 nm at an integrated exposure of 10 to 5,000 J/cm² in an atmospheric environment having an oxygen concentration of 20% to 100% and an ozone concentration of 10 ppm to 500,000 ppm, thereby adsorbing oxygen on the surface of diamond.

2. The diamond surface treatment method according to claim 1, wherein prior to the UV treatment, the diamond can be subjected to a hot mixed-acid treatment.

3. The diamond surface treatment method according to claim 1, wherein the diamond is a crystalline structure selected from the crystalline structured faces (001), (111), and (110), and faces equivalent to the faces in included in the crystalline structured can be adopted.

4. The diamond surface treatment method according to claim 1, wherein diamond thin film to which an impurity capable of forming a p-type or an n-type semiconductor layer is added to the surface of the diamond.

5. The diamond surface treatment method according to claim 4, wherein an impurity capable of forming the n-type semiconductor layer is phosphorous.

6. The diamond surface treatment method according to claim 4, wherein an impurity capable of forming the p-type semiconductor layer is boron.

7. The diamond surface treatment method according to claim 4, wherein on fabrication of an epitaxial diamond thin film by a microwave CVD method, an impurity capable of forming the n-type or the p-type semiconductor layer is added.

8. A diamond Schottky barrier diode including a Schottky electrode and an ohmic electrode are disposed respectively on the upper face and the lower face with a semiconductor diamond layer there between to have a vertical structure, wherein
the diamond Schottky barrier diode is a diamond semiconductor layer the surface oxygen coverage of which is 50% or more.

9. A diamond Schottky barrier diode, wherein a diamond semiconductor layer, the surface oxygen coverage of which is 50% or more, is a diamond semiconductor layer obtained by the diamond surface treatment method according to claim 1.

10. The diamond Schottky barrier diode according to claim 8, wherein Ru, Mo or Pt is used as a Schottky electrode.

11. A sensor device having a small leakage current in a stationary state, wherein the diamond Schottky barrier diode according to claim 8 is used.

12. A diamond pin diode having a vertical structure in which a p-type electrode and an n-type electrode are separately disposed respectively on the upper face and on the lower face, among power semiconductor devices made up of a substrate, a semiconductor, a p-type electrode and an n-type electrode,
wherein
the diamond semiconductor layer is a diamond semiconductor layer obtained by the diamond surface treatment method described in claim 1.

13. A MOS transistor having a vertical structure utilizing a p-type semiconductor or an n-type semiconductor which is comprised of a substrate, a p-type semiconductor, an n-type semiconductor, a gate electrode and a gate insulation film as a drift layer, wherein
the p-type semiconductor or the n-type semiconductor is a diamond semiconductor layer obtained by the diamond surface treatment method according to claim 1.
